(19) United States
(12) Patent Application Publication
(10) Pub. No.: US 2021/0313180 A1
(43) Pub. Date: Oct. 7, 2021

(54) PHOTOVOLTAIC CELL DEVICE AND MANUFACTURING METHOD OF TEMPLATE THEREOF

(71) Applicant: National Central University, Taoyuan (TW)

(72) Inventors: SHENG-HUI CHEN, Hsinchu City (TW); Shao-Ze Tseng, Kaohsiung City (TW); Bo-Huei Liao, Hsinchu City (TW)

(21) Appl. No.: 17/218,378

(22) Filed: Mar. 31, 2021

(30) Foreign Application Priority Data
Apr. 6, 2020 (TW) 109111451

(51) Int. Cl. H01L 21/285; H01L 31/18

(52) U.S. Cl. CPC H01L 21/2855; H01L 31/18

(57) ABSTRACT

A photovoltaic cell device and a manufacturing method of a template thereof are provided. The manufacturing method of the template of the photovoltaic cell device includes the steps of providing a substrate and a target disposed opposite to each other in a chamber, applying an unbalanced magnetic field, and generating a plasma in the chamber to form a sputtered layer on the substrate. The plasma extends to an area proximate to the substrate due to the unbalanced magnetic field to assist the crystallization of the sputtered layer, so that the sputtered layer has a single crystalline or a single crystalline-like structure.

### CROSS-REFERENCE TO RELATED PATENT APPLICATION

This application claims the benefit of priority to Taiwan Patent Application No. 109111451, filed on Apr. 6, 2020. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a photovoltaic cell device and a manufacturing method of a template thereof, and more particularly to a photovoltaic cell device having heterojunctions and a manufacturing method of a template thereof.

### BACKGROUND OF THE DISCLOSURE

A group III-V multi junction solar cell is currently the most efficient solar cell architecture, the highest conversion efficiency record of which has reached 44.7% in 2013. The active area of the solar cell can be reduced and the power conversion efficiency is improved under sunlight concentrated by utilizing a high-magnification optical system.

At present, in order to produce a high-quality group III-V thin film and device, a substrate with a similar lattice constant, for example gallium arsenide (GaAs) or germanium (Ge) single crystal, is usually applied. However, these substrates are usually more expensive, difficult to produce in large sizes, and have poor heat dissipation. In addition, when a germanium solar cell is used as a substrate in a multi junction solar cell, due to the low energy gap of germanium, the generated current is too large to achieve a good current match with the gallium arsenide (GaAS) or indium gallium phosphide (GaInP) on the top layer.

Therefore, at present, it is expected in the industry to replace the originally used gallium arsenide substrate or germanium substrate with silicon (Si), which is most widely used in the electronic industry. This is because silicon is abundant, inexpensive, light-weighted, and has excellent heat dissipation and mechanical strength, etc. In addition, silicon substrate can be produced in large size, greatly reducing the manufacturing cost per device unit, and even facilitating the integration with existing integrated circuit equipment, so as to expand the market applications of the group III-V devices.

However, the lattice constant of silicon does not match the lattice constant of the group III-V material, and it is not easy to grow a high-quality group III-V semiconductor material with high-crystallinity on silicon directly. In order to address the above-mentioned problem, currently, a silicon cell is used as a substrate, and after forming a single crystalline germanium thin film on the silicon cell, a group III-V material is then stacked on the germanium thin film Since silicon has a larger energy gap than that of germanium, the photocurrent converted by its absorption of photons will have a better current match with the high energy gap material on the top layer, thereby improving the operating voltage and conversion efficiency of multi junction solar cells as a whole.

Currently, the formation of a single crystalline germanium thin film on a silicon substrate usually uses a metal organic chemical vapor phase deposition (MOCVD) process or a molecular beam epitaxy (MBE) process. However, the use of a molecular beam epitaxy process requires ultra-high vacuum, the equipment cost is relatively high, and a single crystalline thin film cannot be formed in large area. On the other hand, the use of a metal organic chemical vapor phase deposition process requires toxic gases such as silane or germane, and the process temperature is relatively high. Accordingly, the existing plating technology used to form a single crystalline germanium thin film requires a relatively high processing cost.

### SUMMARY OF THE DISCLOSURE

In response to the above-referenced technical inadequacies, the present disclosure provides a photovoltaic cell device and a manufacturing method of a template thereof to address the problem that the process cost is difficult to reduce.

In order to address the above-mentioned technical problems, one of the solutions adopted by the present disclosure is to provide a manufacturing method of a template of a photovoltaic cell device, including: providing a substrate and a target disposed opposite to each other in a chamber; applying an unbalanced magnetic field within the chamber; and generating a plasma in the chamber to form a sputtered layer on a surface of the substrate, wherein the plasma extends from the target to an area proximate to the substrate due to the unbalanced magnetic field to assist the crystallization of the sputtered layer so that the sputtered layer has a single crystalline or a single crystalline-like structure.

In the process of unbalanced magnetron sputtering deposition, a target disposed facing the substrate and an unbalanced magnetic field are provided. The unbalanced magnetic field has a zero point of magnetic field lines in a normal direction of the target, and a ratio of a width of the target and a vertical distance from the zero point of magnetic field lines to the target ranges from 0.6 to 0.85.

In order to address the above-mentioned technical problems, another solution adopted by the present disclosure is to provide a photovoltaic cell device, which includes a template and a photoelectric conversion layer. The template includes a substrate and an unbalanced magnetron sputtered layer disposed on the substrate, wherein the unbalanced magnetron sputtered layer has single crystalline or single crystalline-like structure. The photoelectric conversion layer is disposed on the unbalanced magnetron sputtered layer.

One of the benefits of the present disclosure is that, the photovoltaic cell device and the manufacturing method of a template thereof provided by the present disclosure can form a sputtered layer having single crystalline or single crystalline-like structure by sputtering at a relatively low process temperature, such that the sputtered layer acts as a buffer layer for the growth of a group III-V semiconductor, through a solution of “providing an unbalanced magnetic field during the sputtering, to drive a magnetic field lines to extend from the target to the substrate, expanding a plasma region, enabling effective improvement in uniformity of its plating energy.” In an embodiment of the present disclosure, by forming a template for the growth of a group III-V semiconductor through a sputtering process, the use of toxic gases can be avoided and a need for an ultra-high vacuum environment is eliminated, thereby reducing the process cost.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The present disclosure will become more fully understood from the following description and the accompanying drawings, in which:

FIG. 1 shows a flowchart of a manufacturing method for forming a template of a photovoltaic cell device according to one embodiment of the present disclosure;

FIG. 2 shows a schematic diagram of a sputtering apparatus used to perform the manufacturing method of FIG. 1 according to one embodiment of the present disclosure;

FIG. 3 shows a schematic diagram of unbalanced magnetic field lines and a plasma range;

FIG. 4 shows an X-ray diffraction (XRD) analysis diagram of a germanium thin film of one embodiment and a comparative example of the present disclosure; and

FIG. 5 shows a schematic diagram of a photovoltaic cell device of one embodiment of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a”, “an”, and “the” includes plural reference, and the meaning of “in” includes “in” and “on”. Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first”, “second” or “third” can be used to describe various components, signals or the like, which are for distinguishing one component/signal from another one only, and are not intended to, nor should be construed to impose any substantive limitations on the components, signals or the like.

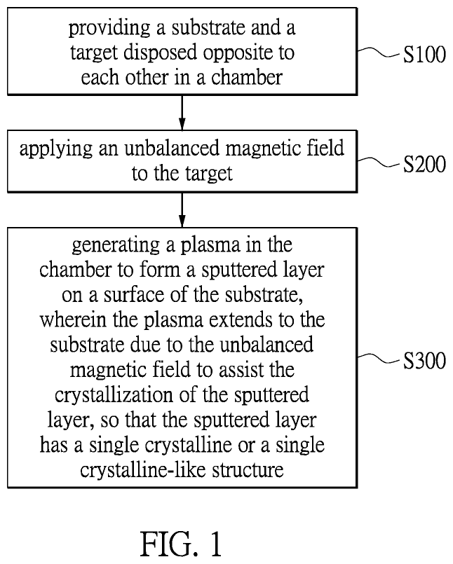

Referring to FIG. 1, FIG. 1 shows a flow diagram of a manufacturing method of a template suitable for the growth of a photovoltaic cell device according to an embodiment of the present disclosure. The manufacturing method provided by the embodiment of the present disclosure can be used to manufacture a template for growing a group III-V photovoltaic cell device at a relatively low process temperature.

It should be noted that sputtering means forming a layer on a substrate based on the principle of momentum transfer. Therefore, the layers formed by sputtering are generally amorphous or polycrystalline. However, an amorphous or polycrystalline layer is not suitable for growing a photovoltaic cell device composed of group III-V semiconductor materials. Accordingly, after forming an amorphous or polycrystalline layer by sputtering, high-temperature annealing processing can be performed to promote the recrystallization of the amorphous or polycrystalline layer. However, through the post-processing, an extra step is added, and it is difficult to reduce the lattice arrangement defects (such as dislocation) in the layers to be suitable for the growth of a high-quality group III-V semiconductor layer.

Accordingly, in an embodiment of the present disclosure, by applying an unbalanced magnetic field, a layer having single crystalline or single crystalline-like structure can be formed by sputtering at a relatively low process temperature.

As shown in FIG. 1, in step S100, a substrate and a target disposed opposite to each other in a chamber are provided. Then, in step S200, an unbalanced magnetic field is applied to the target. In step S300, a plasma is generated in the chamber to form a sputtered layer on a surface of the substrate, wherein the plasma extends to the substrate due to the unbalanced magnetic field to assist the crystallization of the sputtered layer so that the sputtered layer has single crystalline or single crystalline-like structure.

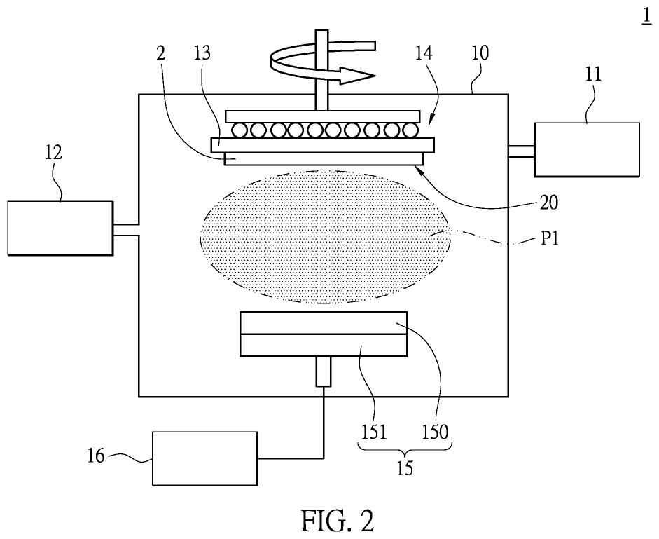

The manufacturing method of the embodiment of the present disclosure may be performed by a sputtering apparatus. Referring to FIG. 2, FIG. 2 shows a schematic diagram of a sputtering apparatus used to perform the manufacturing method of FIG. 1 according to an embodiment of the present disclosure. A sputtering apparatus 1 includes a chamber 10, an exhaust unit 11, a gas supply unit 12, a holder 13, a sputtering gun assembly 15 and a power control module 16.

Both the exhaust unit 11 and the gas supply unit 12 are in fluid communication with the chamber 10. The exhaust unit 11 is used to exhaust a gas inside the chamber 10 so as to maintain a predetermined gas pressure within the chamber 10. The gas supply unit 12 is used to input a gas required during sputtering to the chamber 10. In this embodiment, the gas supply unit 12 may provide at least one of argon gas and hydrogen gas.

The holder 13 and the sputtering gun assembly 15 are both disposed within the chamber 10 and are disposed opposite to each other. The holder 13 is used to fix the substrate 2 within the chamber 10. In an embodiment, the substrate 2 may be a substrate 2 having a crystalline direction, for example, a silicon substrate or a gallium arsenide substrate. In another embodiment, the substrate 2 may also include a silicon-based photoelectric conversion layer. In other embodiments, the substrate 2 may also be an amorphous material, for example, a glass substrate. The substrate 2 has a surface to be plated 20, and is disposed on the holder 13 with the surface to be plated 20 facing the sputtering gun assembly 15.

In addition, the sputtering apparatus 1 in this embodiment further includes a heating element 14, and the heating element 14 is disposed on the back side of the substrate 2, that is, on the side opposite to the surface to be plated 20, to control the temperature of the substrate 2 at a predetermined temperature range. The sputtering gun assembly 15 includes at least one set of targets 150 (one set is depicted in FIG. 2 as an example) disposed within the chamber 10 and a magnetic assembly 151 disposed on a backside surface of the target 150. Specifically, the front face of the target 150 is disposed facing the surface to be plated 20 of the substrate 2, and the magnetic assembly 151 is disposed on the backside surface of the target 150 to generate an unbalanced magnetic field within the chamber 10.

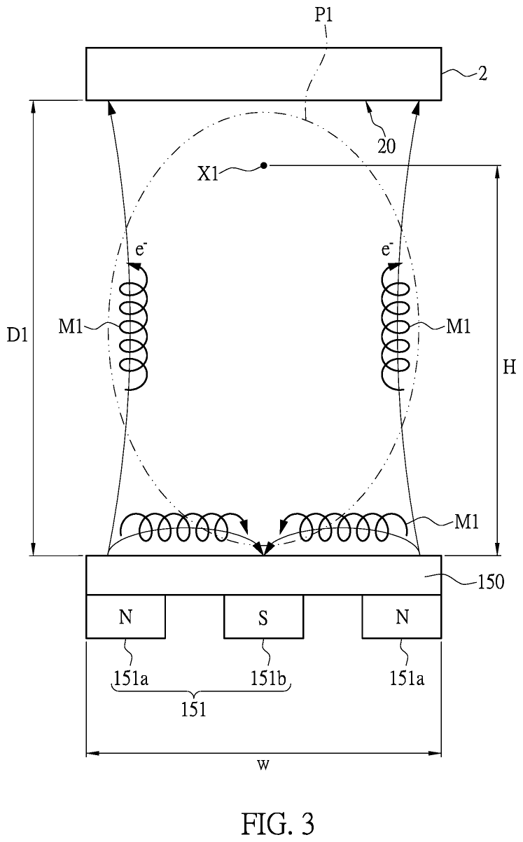

Referring to FIG. 3, in an embodiment, the magnetic assembly 151 includes a plurality of magnetic elements. In an embodiment, the magnetic assembly 151 includes a central magnetic element 151b disposed corresponding in position to the central region of the target 150 and an outer-ring magnetic element 151a disposed corresponding in position to the peripheral region of the target 150. That is, the outer-ring magnetic element 151a is disposed surrounding the central magnetic element 151b.

In addition, by adjusting the magnet strength, arrangement, and number of these magnetic elements, an unbalanced magnetic field can be generated on a surface of the target 150. In an embodiment, the central magnetic element 151b is the S pole, and the outer-ring magnetic element 151a is the N pole, and the magnetic flux of the outer-ring magnetic element 151a is greater than that of the central magnetic element 151b.

Therefore, the magnetic field lines of the outer-ring magnetic element 151a and the central magnetic element 151b are not completely closed on the surface of the target 150, and some of the magnetic field lines will extend to the substrate 2 along the edge of the target 150. In other embodiments, the quantity of the central magnetic element 151b may be smaller than that of the outer-ring magnetic element 151a so that an unbalanced magnetic field is generated.

In addition, in this embodiment, the target 150 and the substrate 2 are separated from each other by a distance D1. A magnitude of the distance D1 will further affect the sputtering rate and the quality of the layer. If the distance D1 between the target 150 and the substrate 2 is too large, during the sputtering, the kinetic energy of atoms sputtered by the target 150 is insufficient to reach the substrate 2 for deposition, which lowers the plating rate and may affect the crystallinity of the layer.

If the distance D1 between the target 150 and the substrate 2 is too small, during the sputtering, the kinetic energy of the atoms sputtered by the target 150 can be so large as to incur damage to the layer that has been deposited on the substrate 2. Accordingly, the target 150 and the substrate 2 can be separated by an appropriate distance according to actual conditions. In an embodiment, depending on the size of the chamber, the distance D1 between the target 150 and the substrate 2 may range from 5 to 10 cm.

Referring again to FIG. 2, the power control module 16 is electrically connected to the sputtering gun assembly 15 and the holder 13, and is used to provide power to the target 150 so as to generate a high voltage electric field within the chamber 10. The power control module 16 may include a radio frequency power supply, a DC power supply, a pulse power supply, or a combination thereof.

In view of the above, after the substrate 2 is disposed on the holder 13, the vacuum degree inside the chamber 10 is initially rendered to be lower than 10-6 torr by means of the exhaust unit 11. Then, a control valve of the gas supply unit 12 is opened, so that a gas (for example, argon gas) enters the chamber 10 until the vacuum degree of the chamber 10 reaches a predetermined value.

Next, the power control module 16 is turned on to generate a high voltage electric field within the chamber 10, which promotes gas ionization to generate a plasma P1. It should be noted that the vacuum degree is inversely correlated to the plasma density. That is, the higher the vacuum degree is, the less the number of gas molecules are, and the lower the plasma density is. However, an excessively low plasma density will cause a reduction in the number of positive ions hitting the target, resulting in a decrease in plating rate, or affecting the crystallinity of the layer. Therefore, in this embodiment, after the gas is introduced, the vacuum degree within the chamber 10 is maintained at 2×10-2 to 5×10-4 torr.

After the plasma P1 is generated within the chamber 10, the positive ions of the plasma P1 will hit the target 150 to which a negative bias voltage is applied, so that atoms in the target 150 are sputtered out and then deposited onto the substrate 2.

References are made to FIGS. 2 and 3. Since the magnetic field lines M1 of the unbalanced magnetic field generated by the magnetic assembly 151 extend to the substrate 2, the secondary electrons in the plasma P1 extend along the magnetic field lines M1 toward the substrate 2. The secondary electrons will dissociate the gas in the vicinity of the substrate 2 so that the plasma P1 extends from the surface of the target 150 to the surface to be plated 20 of the substrate 2. Accordingly, the plasma P1 will be more evenly distributed in the space between the target 150 and the substrate 2 without being limited to only a region adjacent to the target 150.

With respect to the target 150, the substrate 2 is applied with a positive bias voltage. Therefore, after the atoms of the target 150 are deposited onto the substrate 2, the charged particles (electrons) in the plasma P1 can give energy to the atoms that have been deposited on the substrate 2, so that the atoms can be rearranged along the crystallization direction for crystallization. That is, during the film formation by sputtering, the plasma P1 can also assist the crystallization of the layer. Accordingly, the sputtered layer prepared by the unbalanced magnetron sputtering step may have single crystalline or single crystalline-like structure.

In addition, referring to FIG. 3, the unbalanced magnetic field has a zero point X1 of magnetic field lines in a normal direction of the target 150. A ratio G (i.e., w/H) between a width w of the target 150 and a vertical distance H from the zero point X1 of magnetic field lines to the surface of the target 150 affects the range of the plasma P1. When the ratio G is larger, most of the magnetic field lines M1 will be closed at the surface of the target 150, and the range of the plasma P1 will be limited to the region in the vicinity of the target 150 and becomes smaller.

When the ratio G is smaller, most of the magnetic field lines M1 will extend to the substrate 2 and expand the range of the plasma P1. In an embodiment, the ratio G between the width w of the target 150 and the vertical distance H from the zero point X1 of magnetic field lines to the surface of the target 150 ranges from 0.6 to 0.85. In this way, the plasma P1 can extend to the vicinity of the substrate 2 to assist the crystallization of the sputtered layer.

In addition, a distance D1 between the target 150 and the substrate 2 ranges from 5 cm to 10 cm. It is worth mentioning that, in an embodiment of the present disclosure, through an unbalanced magnetron sputtering step, a sputtered layer having single crystalline or single crystalline-like structure can be formed on the substrate at a relatively low substrate temperature.

The substrate 2 may be a silicon substrate with a crystalline direction or a group III-V semiconductor substrate, and the material constituting the sputtered layer may be germanium, gallium arsenide, silicon germanium, silicon, gallium nitride, zinc oxide, and doped compounds thereof.

When the substrate 2 is a silicon substrate with a crystalline direction, and the material of the sputtered layer is germanium or silicon germanium, the temperature of the substrate 2 may range from 250 to 550° C. Compared with the process temperature (approximately 700° C.) when forming single crystal germanium or silicon germanium on a silicon substrate through metal organic chemical vapor phase deposition, the manufacturing method provided by the embodiment of the present disclosure has a lower process temperature. Accordingly, during temperature increasing and decreasing, the residual stress caused by the difference in thermal expansion coefficient between the sputtered layer and the substrate 2 can be reduced.

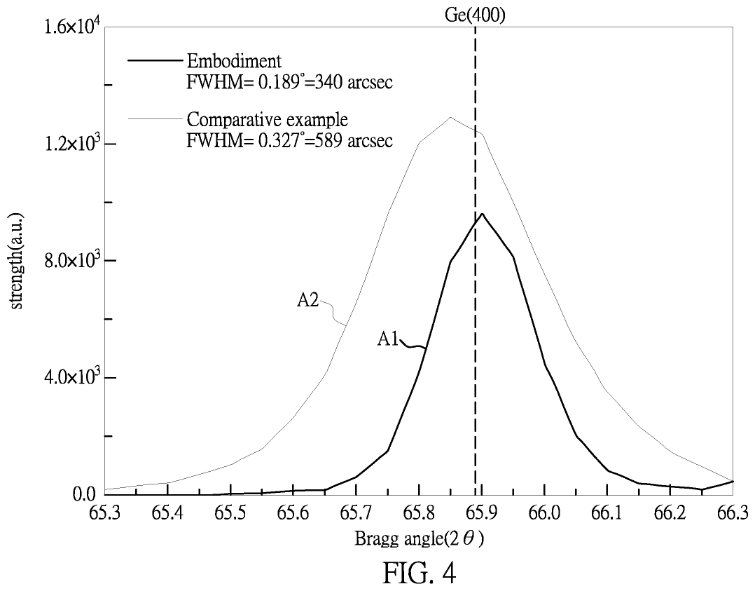

On the other hand, the sputtered layer (e.g., silicon germanium layer or germanium layer) formed by the unbalanced magnetron sputtering process of the embodiment of the present disclosure can be used as a buffer layer between the group III-V semiconductor layer and the silicon substrate, due to having single crystalline or single crystalline-like structure and having a lattice constant that can match the lattice constant of a group III-V semiconductor layer (such as gallium arsenide and gallium nitride). That is, the manufacturing method provided by the embodiment of the present disclosure is indeed applicable for the manufacturing of a template for the growth of a photovoltaic cell device. Referring to FIG. 4, FIG. 4 shows an X-ray diffraction (XRD) analysis diagram of a germanium thin film of an embodiment and a comparative example of the present disclosure. Curve A1 shows an X-ray diffraction analysis of a germanium thin film formed on a silicon substrate by unbalanced magnetron radio frequency sputtering (application of an unbalanced magnetic field). Curve A2 shows an X-ray diffraction analysis of a germanium thin film formed on a silicon substrate by balance magnetron radio frequency sputtering (application of a balance magnetic field). The diffraction peaks of curves A1 and A2 all correspond to the (400) plane of germanium crystals.

The full width at half maximum (FWHM) of diffraction peak of curve A1 is about 0.189°, and the full width at half maximum of diffraction peak of curve A2 is about 0.327°. That is, a germanium thin film formed utilizing unbalanced magnetron radio frequency sputtering has a larger crystal grain size and has better crystallinity, compared to the germanium thin film formed utilizing balance magnetron radio frequency sputtering.

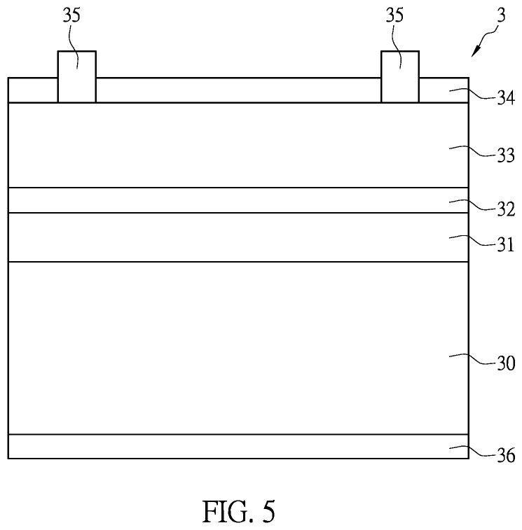

Referring to FIG. 5, a schematic diagram of a photovoltaic cell device of an embodiment of the present disclosure is shown. The photovoltaic cell device 3 includes a template and a photoelectric conversion layer 33 disposed on the template.

The template may be manufactured by the aforementioned manufacturing method, and may include a substrate 30 and an unbalanced magnetron sputtered layer 31 disposed on the substrate 30. In an embodiment, the substrate 30 may be a silicon substrate having a crystal direction or a group III-V semiconductor substrate.

The unbalanced magnetron sputtered layer 31 has single crystalline or single crystalline-like structure, and can be formed on the substrate 30 by the aforementioned manufacturing method. The material constituting the unbalanced magnetron sputtered layer 31 can be selected from at least one of germanium, gallium arsenide, silicon germanium, silicon, gallium nitride, zinc oxide, and doped compounds thereof.

The photoelectric conversion layer 33 may be a silicon-based photoelectric conversion layer, a germanium-based photoelectric conversion layer, or a group III-V semiconductor photoelectric conversion layer. When the substrate 30 is a silicon substrate and the photoelectric conversion layer 33 is a group III-V semiconductor photoelectric conversion layer, the unbalanced magnetron sputtered layer 31 can serve as a buffer layer for growth of the group III-V semiconductor photoelectric conversion layer. Specifically, the material of the unbalanced magnetron sputtered layer 31 may be germanium or silicon germanium, which has a lattice constant that can match the lattice constant of the group III-V semiconductor layer.

In another embodiment, the photovoltaic cell device 3 is a multi junction photovoltaic cell device, that is, it has multiple PN junctions, which can absorb and convert light beams with different wavelengths. In this embodiment, the substrate 30 may also include a silicon-based photoelectric conversion layer. In addition, the photovoltaic cell device may further include a tunneling layer 32 between the photoelectric conversion layer 33 and the unbalanced magnetron sputtered layer 31, as shown in FIG. 4. The material constituting the tunneling layer 32 may be a group III-V semiconductor.

Referring to FIG. 4, the photovoltaic cell device 3 may further include an anti-reflection layer 34, an upper electrode layer 35 and a lower electrode layer 36. The anti-reflection layer 34 is disposed on the photoelectric conversion layer 33 to increase the conversion efficiency of the photovoltaic cell device 3. The upper electrode layer 35 is located above the anti-reflection layer 34, and the lower electrode layer 36 is located at the bottom of the substrate 30 to output the photocurrent generated by the photovoltaic cell device 3.

### Benefits of the Embodiments

In summary, one of the benefits of the present disclosure is that the manufacturing method of a template for the growth of a photovoltaic cell device provided by the present disclosure provides an unbalanced magnetic field during the sputtering process such that magnetic field lines extend from the target toward the substrate, expanding the region of the plasma P1, and thus improving the uniformity of the plating energy.

Further, the manufacturing method of a sputtered layer provided by the present disclosure can form a sputtered layer having single crystalline or single crystalline-like structure at a relatively low substrate temperature, by making a ratio G between a width w of the target 150 and a vertical distance from the zero point X1 of magnetic line of force to the target 150 in the range of 0.6 to 0.85. Accordingly, in addition to reducing the processing cost and expanding the selection range of the substrate, the residual stress between the layer and the substrate due to the difference in thermal expansion coefficient can also be reduced.

In addition, the sputtered layer having single crystalline or single crystalline-like structure can also be used as a buffer layer between the silicon substrate and the group III-V semiconductor material layer, so that it can be applied to a photovoltaic device with heterojunctions.

Compared to forming a buffer layer through processes such as a metal organic chemical vapor phase deposition process and a molecular beam epitaxy process, the unbalanced magnetron sputtering process provided by an embodiment of the present disclosure does not require the use of toxic gases and ultra-high vacuum equipment, so that the manufacturing costs can be greatly reduced. In addition, an unbalanced magnetron sputtering process is advantageous for mass production due to a faster plating rate.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated.

Alternative embodiments will become apparent to those skilled in the art to which the present disclosure pertains without departing from its spirit and scope.

What is claimed is:

1. A manufacturing method of a template of a photovoltaic cell device, comprising:
providing a substrate and a target disposed opposite to each other in a chamber;
applying an unbalanced magnetic field; and
generating a plasma in the chamber to form a sputtered layer on a surface of the substrate, wherein the plasma extends to an area proximate to the substrate due to the unbalanced magnetic field to assist the crystallization of the sputtered layer so that the sputtered layer has a single crystalline or a single crystalline-like structure.

2. The manufacturing method of claim 1, wherein the unbalanced magnetic field has a zero point of magnetic field lines in a normal direction of the target, and a width of the target and a vertical distance from the zero point of magnetic field lines to the surface of the target satisfies the following relationship: G=w/H, wherein w is the width of the target, H is the vertical distance from the zero point of magnetic field lines to the surface of the target, and G ranges from 0.6 to 0.85.

3. The manufacturing method of claim 1, wherein the target and the substrate are separate from each other by a distance ranging from 5 to 10 cm.

4. The manufacturing method of claim 1, wherein the substrate is a silicon substrate with a crystalline direction, and the sputtered layer is made of at least one of germanium, gallium arsenide, silicon germanium, silicon, gallium nitride, zinc oxide, and doped compounds thereof.

5. The manufacturing method of claim 1, wherein, in the step of generating the plasma in the chamber to form the sputtered layer, the temperature of the substrate ranges from 250 to 550° C., and the material constituting the single crystalline or the single crystalline-like layer is germanium, gallium arsenide, silicon germanium, silicon, gallium nitride, zinc oxide and doped compounds thereof.

6. The manufacturing method of claim 1, wherein the unbalanced magnetron field is generated by disposing a magnetic assembly on a backside surface of the target, wherein the magnetic assembly includes a central magnetic element and an outer-ring magnetic element disposed surrounding the central magnetic element, and the magnetic flux of the outer-ring magnetic element is greater than that of the central magnetic element.

7. A photovoltaic cell device, comprising:
a template including a substrate and an unbalanced magnetron sputtered layer disposed on the substrate, wherein the unbalanced magnetron sputtered layer has a single crystalline or a single crystalline-like structure; and
a photoelectric conversion layer disposed on the unbalanced magnetron sputtered layer.
